(19) United States
(12) Patent Application Publication
(10) Pub. No.: US 2003/0221623 A1
(43) Pub. Date: Dec. 4, 2003

(54) Fabricating a semiconductor device

(75) Inventors: Nobuhito Shima, Tokyo (JP); Tomoshi Taniyama, Tokyo (JP); Shigeru Odake, Tokyo (JP); Tomoharu Shimada, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Tokyo (JP)

(21) Appl. No.: 10/452,250

(22) Filed: Jun. 3, 2003

(30) Foreign Application Priority Data
Jun. 3, 2002 (JP) 2002-161390

(51) Int. Cl. C23C 16/00

(52) U.S. Cl. 118/724; 432/241

(57) ABSTRACT

An apparatus for fabricating a semiconductor device includes a reaction or process tube provided with at least one reinforcement member. The reinforcement member is attached to a body portion of the reaction tube and extends in a longitudinal direction of the reaction tube. A heater surrounds the reaction tube and a substrate loaded in the reaction tube is heat-treated by the heater.

### FIELD OF THE INVENTION

The present invention relates to an apparatus and method for fabricating a semiconductor device; and, more particularly, to a technique useful for applications to a furnace which performs various heat treatments, such as an oxidation treatment, a diffusion treatment, and reflowing/annealing for an activation or a planarization of a carrier after ion implantation, on a semiconductor wafer (hereinafter, referred to as “wafer”) in which an integrated circuit (IC) device is formed.

### BACKGROUND OF THE INVENTION

In manufacturing an IC device, a batch type vertical hot wall furnace (or hot wall type heat treatment apparatus) (hereinafter, referred to as “hot wall furnace”) is widely used in heat treatments such as an annealing. The hot wall furnace includes a process or reaction tube forming a processing chamber into which wafers are introduced, the process tube being a cylindrical tube made of quartz and having a closed top end; a heater disposed outside the process tube; a thermal diffuser tube provided for the uniformity of temperature and for the reduction of contaminants inside the processing chamber, the thermal diffuser tube being disposed between the process tube and the heater; and a boat for holding a plurality of wafers in a concentric vertical array and for loading and unloading the wafers into and from the processing chamber. The wafers are loaded by the boat into the processing chamber through a furnace opening and then heated by the heater to thereby heat-treat the wafers in a batch process.

The conventional process tube for use in the hot wall furnace is made of quartz for the following reasons: The quartz (i) does not act as a source of contamination since it has only a very small amount of impurities, (ii) has a low thermal expansion coefficient, and (iii) has a high transmittance. Such a quartz process tube generally includes a top wall having a flat shape as shown in FIG. 1A or a curved shape as shown in FIG. 1B.

Since, however, a viscous flow takes place in such a process tube made of quartz when the heat treatment temperature is equal to or greater than 900° C., there occur such problems that the top wall of the process tube sags or is bent down as indicated by the arrow A in FIG. 2, a body portion swells as indicated by the arrow B in FIG. 2, and/or the body portion is shrunken as indicated by the arrow C in FIG. 2. As the heat treatment temperature is increased, such deformations of the process tube become more significant. Moreover, an internal viscous flow becomes intense in a region of a distortion point or an annealing point at 1000° C. or higher, and thus a creep deformation may occur due to its own weight of the process tube. Further, such a deformation is affected by the compositions of the quartz material. In general, since a process tube made of synthetic quartz with impurities less than those of natural quartz contains a great number of OH group and thus has a high viscous flow, deformations become more likely to occur.

Though varying depending on the nature of treatment, the heat treatment is typically carried out at a temperature near 1200° C. that is high enough to cause the internal viscous flow of the quartz process tube. Further, in case the creep deformation by the weight of the process tube itself occurs and progresses, there may be caused a failure due to the deterioration in strength of the process tube or a failure due to the interference of the boat. In particular, when an explosive gas such as hydrogen (H₂) is employed, attention should be paid to the failure of the process tube since it may cause a gas explosion. Further, in case the temperature inside the heater is rapidly increased or decreased to shorten the tact time of the hot wall furnace, a great heat stress is applied to the process tube, thereby resulting in a decrease in strength of the process tube.

The thickness of the wall of the process tube ranges typically 3 mm to 8 mm. If the thickness of the wall of the process tube is increased, it is advantageous in terms of the thermal deformations due to its own weight; but the tact time of the hot wall type furnace increases accordingly since the thermal response in the processing chamber of the process tube is deteriorated.

### SUMMARY OF THE INVENTION

It is, therefore, an object of the present invention to provide an apparatus and method for fabricating a semiconductor device, wherein the durability of a process tube is extended, thereby reducing the running cost of the apparatus while increasing safety or operation efficiency.

In accordance with an aspect of the present invention, there is provided an apparatus for fabricating a semiconductor device including:

a reaction or process tube provided with at least one reinforcement member or rib which is attached to a body portion of the reaction tube, the reinforcement member being extended in a longitudinal direction of the reaction tube; and

a heater surrounding the reaction tube, wherein a substrate loaded in the reaction tube is heat-treated by the heater.

Preferably, the body portion of the reaction tube has an open end and a closed end opposite thereto, and the reinforcement member provided is extended from the open end toward the closed end in the longitudinal direction.

The closed end of the reaction tube is substantially located vertically above the open end.

Preferably, a flange is provided to the open end of the reaction tube, and the reinforcement member provided is extended from the flange toward the closed end.

The closed end of the reaction tube constitutes a closed wall, and a reinforcement member is provided on the closed wall.

The reinforcement provided on the body portion is continuous to the reinforcement member provided on the closed wall.

The number of the reinforcement members provided on the body portion of the reaction tube is two or more, and the reinforcement members are circumferentially arranged at regular intervals around the body portion of the reaction tube.

Preferably, at least one ring-shaped reinforcement member is horizontally disposed around the body portion of the reaction tube.

In accordance with an aspect of the present invention, there is provided a method for fabricating a semiconductor device using a semiconductor device fabricating apparatus including a reaction tube having a body portion with one end opened and the other end closed, at least one reinforcement member being provided on the body portion of the reaction tube, the reinforcement member being extended from the open end toward the closed end therebetween, and a heater surrounding the reaction tube, the method comprising the steps of:

loading a substrate holding member on which a plurality of wafers are placed into the reaction tube;

heating the plurality of wafers by the heater; and

unloading the boat holding the plurality of wafers heated from the reaction tube.

### BRIEF DESCRIPTION OF THE DRAWINGS

The above and other objects and features of the present invention will become apparent from the following description, of preferred embodiments given in conjunction with the accompanying drawings in which:

FIG. 1A presents a longitudinal-section view of a prior art process tube with a top portion having a planar shape;

FIG. 1B shows a longitudinal-section view of a prior art process tube with a top portion having a curved shape;

FIG. 2 is a longitudinal-section view of a prior art process tube showing heat deformations;

FIG. 3 is a longitudinal-section view of a hot wall furnace in accordance with a preferred embodiment of the present invention showing a state prior to a boat loading step;

FIG. 4 sets forth a longitudinal-section view showing a heat treatment step in the furnace of FIG. 3;

FIGS. 5A and 5B depict a plan view and a front view of a process tube in accordance with a first preferred embodiment of the present invention, respectively;

FIG. 6 offers a graph showing a temporal temperature profile of an annealing process for fabricating an IC device in accordance with a preferred embodiment of the present invention;

FIGS. 7A and 7B depict a plan view and a front view of a process tube in accordance with a second preferred embodiment of the present invention, respectively;

FIGS. 8A and 8B present a plan view and a front view of a process tube in accordance with a third preferred embodiment of the present invention, respectively;

FIGS. 9A and 9B set forth a plan view and a front view of a process tube in accordance with a forth preferred embodiment of the present invention, respectively;

FIGS. 10A and 10B show a plan view and a front view of a process tube in accordance with a fifth preferred embodiment of the present invention, respectively;

FIGS. 11A and 11B set forth a plan view and a front view of a process tube in accordance with a sixth preferred embodiment of the present invention, respectively;

FIGS. 12A and 12B depict a plan view and a front view of a process tube in accordance with a seventh preferred embodiment of the present invention, respectively; and

FIGS. 13A and 13B are a plan view and a front view of a process tube in accordance with an eighth preferred embodiment of the present invention, respectively;

### DETAILED DESCRIPTION OF THE PREFERRED EMBODIMENTS

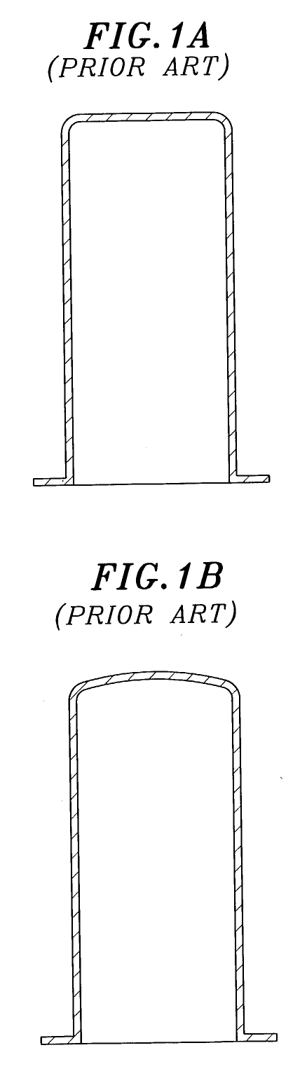

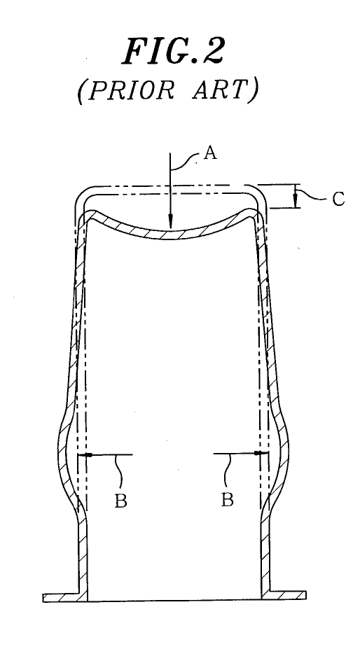

Preferred embodiments of the present invention will now be described in detail with reference to the accompanying drawings, wherein like reference numerals appearing in FIGS. 1 to 13B represent like parts.

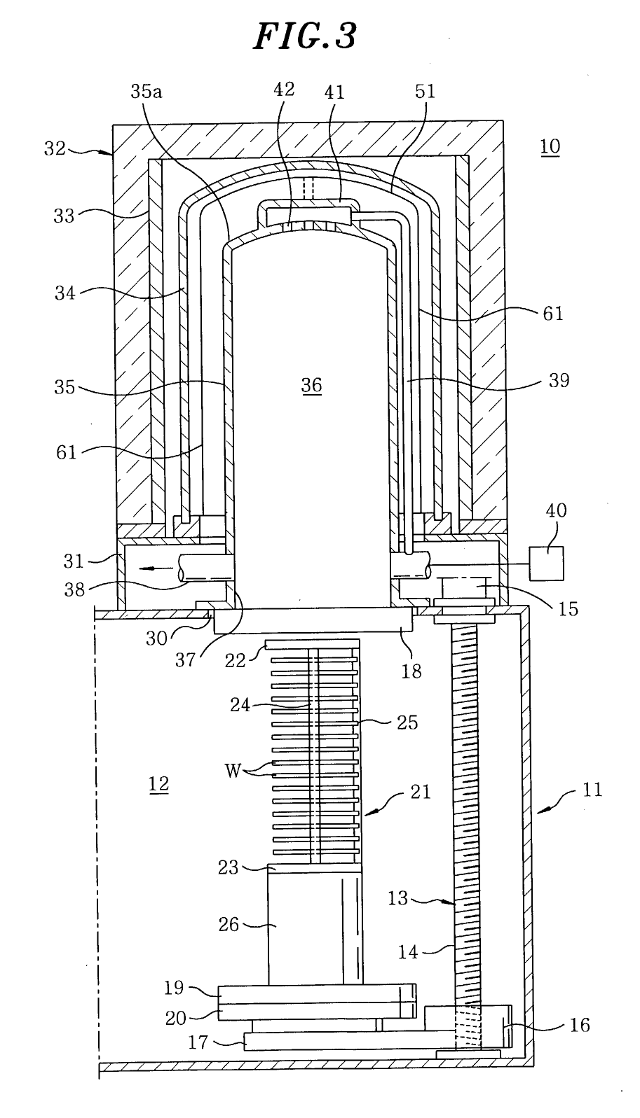

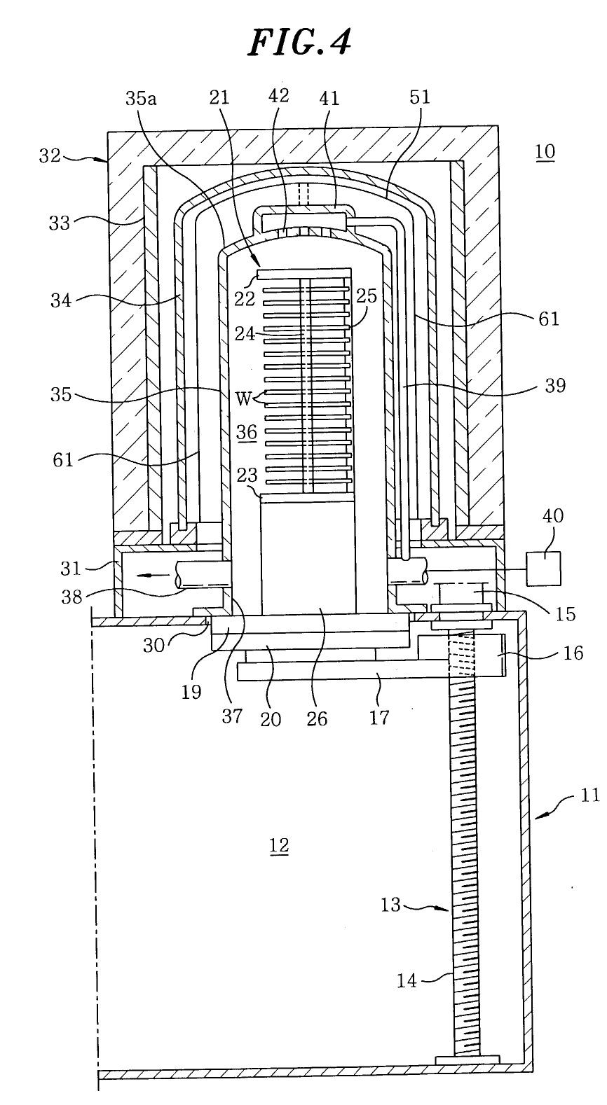

As shown in FIGS. 3 and 4, an apparatus for fabricating a semiconductor device in accordance with a preferred embodiment of the present invention is constructed as a hot wall furnace (a batch type vertical hot wall furnace) 10 carrying out heat treatments in a process for fabricating IC devices.

The hot wall furnace 10 shown in FIGS. 3 and 4 includes a housing 11 constructed in a generally cubic box shape to form an air-tight chamber. The air-tight chamber of the housing 11 serves as a waiting chamber 12 in which a boat 21 stands by before being loaded into and after being unloaded from a processing chamber 36. A boat elevator 13 is disposed in the waiting chamber 12 for moving up and down the boat 21. The boat elevator 13 includes a transfer screw shaft 14 which is vertically and rotatably installed in the waiting chamber 12; a motor 15 for rotating the transfer screw shaft 14, the motor 15 being disposed outside the waiting chamber 12; an elevator member 16 for ascending and descending depending on the rotation of the transfer screw shaft 14, the elevator member 16 being screw-coupled with the transfer screw shaft 14; and a support arm 17 horizontally extended from the elevator member 16. A seal cap 20 for closing the processing chamber 36 is horizontally supported on the leading portion of the support arm 17. The seal cap 20 has a disk shape with an outer diameter substantially same as that of a process or reaction tube 35. The boat 21 is vertically centrally disposed on the seal cap 20 via a base 19.

The boat 21 includes an upper and a lower plates 22, 23, and a plurality of, e.g., three, holding members 24 vertically extending therebetween. Each of the three holding members 24 is provided with a multiplicity of vertically spaced holding slots 25 for receiving and holding wafers W, each set of corresponding horizontal slots 25 of the holding members 24 being at a same level and opened toward each other. Each of the wafers W is inserted into a set of corresponding holding slots 25 and thus the boat 21 holds the multiplicity of wafers W horizontal and concentric with each other. Disposed between the boat 21 and the seal cap 20 is a thermal insulating cap portion 26 in which a thermal insulating material is filled. The boat 21 is supported by the thermal insulating cap portion 26 such that it is lifted up from a top surface of the seal cap 20, and a bottom end of the boat 21 is separated by an appropriate distance from a furnace opening 37 of the processing chamber 36.

In a top wall of the waiting chamber 12, a boat loading/unloading port 30 is formed immediately above the boat 21. Further, on the top wall of the waiting chamber 12, a scavenger 31 is disposed surrounding the boat loading/unloading port 30. A thermal insulating member 32 of a cylindrical shape with a top end closed is vertically disposed on the scavenger 31. A heater 33 formed of an electrical resistance material is spirally disposed around an inner periphery of the thermal insulating member 32. The heater 33 is controlled by a temperature controller (not shown) such that the temperature in the processing chamber 36 is sequence-controlled and feedback-controlled.

Inside the heater 33, a thermal diffuser tube 34 is concentrically and vertically disposed on the scavenger 31. A process tube (which is also referred to as “reaction tube”) 35 is concentrically disposed inside the thermal diffuser tube 34. The thermal diffuser tube 34 is made of silicon carbide (SiC) or quartz and has a cylindrical shape with an outer diameter smaller than an inner diameter of the heater 33. The thermal diffuser tube 34 having a closed upper end and an open lower end concentrically surrounds the process tube 35. The process tube 35 is disposed concentrically with the boat loading/unloading port 30 and supported by the top wall of the waiting chamber 12 of the housing 11. The gap between the bottom end of the process tube 35 and the lower end of the thermal diffuser tube 34 is air-tightly sealed with the scavenger 31.

The process tube 35 is made of quartz and has a cylindrical shape with a closed top end and an open bottom end. The inner space of the process tube 35 forms a processing or reaction chamber 36 into which a number of wafers held and stacked vertically by the boat 21 are loaded. An opening in the bottom end of the process tube 35 serves as a furnace opening 37 through which the wafers are loaded and unloaded. An inner diameter of the process tube 35 is set to be larger than a maximum diameter (e.g., 300 mm) of the wafers to be treated. A gas exhausting line 38 is at one end connected to a lower end portion of the process tube 35, and at the other end to an exhaust device (not shown) to allow the processing chamber to be evacuated. Inserted in the scavenger 31 is a gas supplying line 39 connected to a gas supply device 40 for supplying a reaction gas, a carrier gas or the like. The gas supplying line 39 extends upwardly along the side wall of the process tube 35 and is connected to a buffer chamber 41 formed above a top portion 35a of the process tube 35 to communicate therewith. Inside the buffer chamber 41, plural gas ejection openings 42 are formed in the top portion 35a of the process tube 35. The gas introduced into the buffer chamber 41 from the gas supplying line 39 diffuses in the buffer chamber 41 and is ejected in a shower fashion through the gas ejection openings 42 into the processing chamber 36. The gas introduced into an upper portion in the processing chamber 36 from the gas ejection openings 42 flows downwardly in the processing chamber 36 and is exhausted through the gas exhausting line 38.

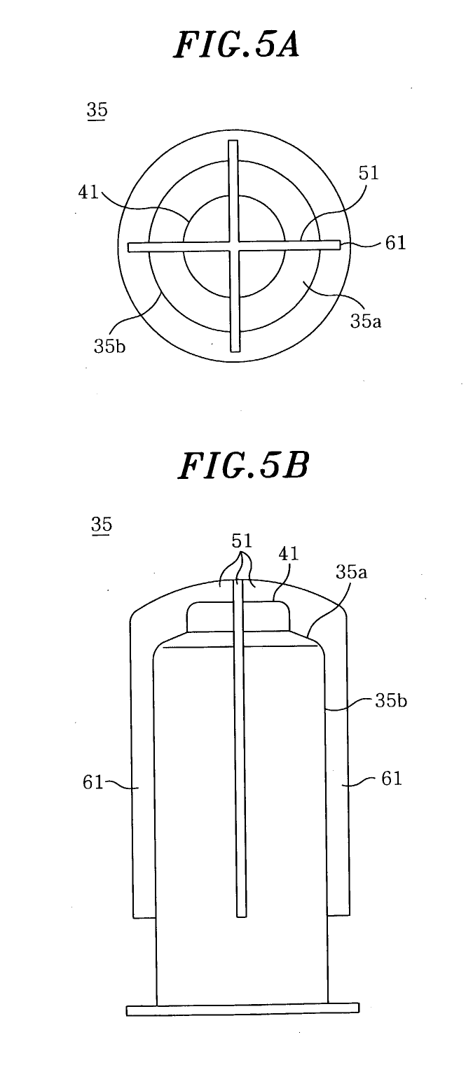

As shown in detail in FIGS. 5A and 5B, top portion reinforcement ribs 51 and body portion reinforcement ribs 61 are attached to the process tube 35 in order to confer thereto a resistive force against a thermal deformation due to its own weight. Each of the top portion reinforcement ribs 51 and the body portion reinforcement ribs 61 is formed in a generally rectangular planar plate shape using quartz of the same quality as that of the process tube 35. The top portion reinforcement ribs 51 are set to exhibit a resistive force against sagging or bending of the top portion 35a of the process tube 35 and have a cross shape extending through the center point of the top portion 35a along the curved surface thereof. Preferably, each of the top portion reinforcement ribs 51 has a constant width and a constant height and is attached at right angle to the surface of the top portion 35a by, e.g., welding. The body portion reinforcement ribs 61 are set to have a great moment of inertia of area (or second moment of area) for exhibiting a resistive force against a buckling and a longitudinal shrinkage of a body portion 35b of the process tube 35. The body portion reinforcement ribs 61 are formed of four rectangular flat plates which are continuously linked to four lower ends of the top portion reinforcement ribs 51, respectively, and attached at right angle to an outer periphery of the process tube 35 by, e.g., welding. Bottom ends of the body portion reinforcement ribs 61 are substantially flushed with a bottom end of the heater 33. This is because a viscous flow occurs in the upper portion of the process tube 35 which has been heated by the heater 33, but no viscous flow occurs in the lower portion of the process tube 35 which has not been heated by the heater 33. As a result, if the body portion reinforcement ribs 61 are extended over portions at different temperatures, they restrict the thermal expansion of the process tube 35, thereby resulting in a development of internal stress in the process tube 35. Therefore, in order to prevent the generation of internal stress in the process tube 35, the body portion reinforcement ribs 61 are preferably not extended over the portions at different temperatures.

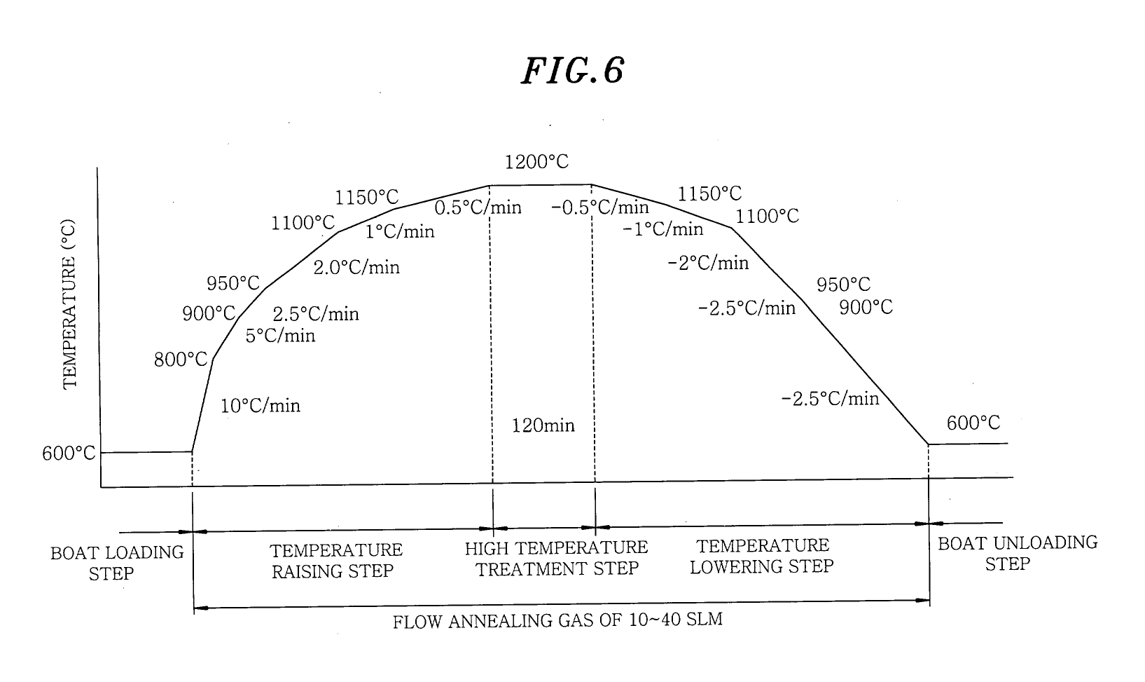

There will now be described with reference to FIG. 6 an annealing process for fabricating a Denuded Zone (“DZ”) wafer (hereinafter, referred to as “DZ wafer”) as a replacement of an epitaxial wafer using the hot wall furnace having the configuration described above.

As illustrated in FIG. 3, the wafers to be annealed are loaded by a wafer transfer unit (not shown) on the boat 21 which stands by in the waiting chamber 12. At this time, the furnace opening 37 of the process tube 35 is closed with a shutter 18, so that the heat in the processing chamber 36 does not penetrate into the waiting chamber 12.

After a predetermined number of wafers are loaded on the boat 21, at a boat loading step indicated in FIG. 6, the boat 21 is lifted up by the boat elevator 13 and inserted (boat-loaded) into the processing chamber 36 through the furnace opening 37 of the process tube 35. As shown in FIG. 4, the boat 21 is then disposed in the processing chamber 36 while being supported by the seal cap 20. As shown in FIG. 6, the temperature in the processing chamber 36 is maintained at a predetermined standby temperature of 600° C. until a temperature raising step begins.

When the boat 21 is disposed in the processing chamber 36, the processing chamber 36 is heated by the heater 33 and, therefore, the temperature therein is raised in a temperature sequence as shown in FIG. 6. At this time, the difference between a target temperature in a sequence control of the heater 33 and an actual temperature raised is corrected by a feedback control.

As shown in FIG. 6, after the temperature of the processing chamber 36 reaches 1200° C. at a high temperature treatment step which is predetermined as an appropriate temperature of the annealing treatment, it is constantly maintained at 1200° C. At this time, even if an internal viscous flow occurs in the process tube 35, the thermal deformation by its own weight is prevented due to the top portion reinforcement ribs 51 and the body portion reinforcement ribs 61 attached thereto.

As shown in FIG. 6, after 120 minutes, a predetermined treatment time period of the high temperature treat step, has lapsed, the temperature in the processing chamber 36 is lowered in accordance with a temperature sequence of a temperature lowering step as indicated in FIG. 6. At this time, though a heat capacity of the process tube 35 is increased in proportion to the increase in the mass of the top portion reinforcement ribs 51 and the body portion reinforcement ribs 61 attached thereto. The prolongation of the time period required to lower the temperature in the processing chamber 36 of the process tube 35 down to the predetermined standby temperature can be prevented since the top portion reinforcement ribs 51 and the body portion ribs 61 attached to the outer surface of the process tube 35 serve as cooling fins.

After the temperature in the processing chamber 36 reaches 600° C. which is the predetermined standby temperature, it is maintained constant thereat. Then at a boat unloading step, the seal cap 20 is lowered by the boat elevator 13 and the furnace opening 37 is opened. The treated wafers are then unloaded from the processing chamber 36 into the waiting chamber 12 while being held by the boat 21. As shown in FIG. 3, after the boat 21 is unloaded into the waiting chamber 12, the furnace opening 37 of the processing chamber 36 is closed by the shutter 18, and the treated wafers W are discharged from the boat 21 by the wafer transfer unit (not shown).

In the annealing process described above, as shown in FIG. 6, argon (Ar) gas as the annealing gas flows at 10˜40 SLM (Standard Litter per Minute) from the beginning of the temperature raising step to the end of the temperature lowering step.

In a process for fabricating the DZ wafer by the annealing treatment, hydrogen gas or argon gas is used as the annealing gas. In case the hydrogen gas is used, the depth of the DZ can be greater than that for the case of using the argon gas. In other words, the hydrogen gas becomes reductive under a high temperature condition, and reacts with oxygen in silicon and an oxide film of the wafer and quartz to produce H₂O. Further, under the high temperature condition, oxygen diffuses from the wafer into the atmosphere. As such, the oxygen contained in silicon is removed so that the DZ wafer can be fabricated.

However, argon gas is used in the process for fabricating the DZ wafer in accordance with the preferred embodiment of the present invention for the following reasons:

1) Also by the annealing treatment using argon gas, the DZ wafer can be manufactured.

2) Argon gas can reduce the production cost in comparison with hydrogen gas.

3) The annealing treatment by argon gas produces less contaminants than the treatment by hydrogen gas. That is, the process tube made of quartz is eroded by the reduction process of hydrogen gas and, therefore, contaminant elements contained in quartz of the process tube are released in a gaseous phase (into the processing chamber); and the released contaminant elements are deposited onto the wafer, thereby resulting in the contamination of the wafer. To the contrary, since the inert argon gas does not react with the wafer and the quartz process tube, impurities from the wafer diffuse out in the gaseous phase under the high temperature condition, so that the DZ wafer can be manufactured.

In accordance with this preferred embodiment, the following effects are obtained.

1) Since the mechanical strength of the process tube is increased due to the top portion and the body portion reinforcement ribs attached to the outer surface of the process tube, thermal deformations by its own weight is prevented even if the internal viscous flow of the process tube may occur. As a result, the durability of the process tube can be extended, and the running cost of the IC device manufacturing process can be reduced.

2) As the thermal deformation of the process tube at a high temperature is prevented, the process tube can be made of synthetic quartz which has been known to be improper to be used under a high temperature condition due to its high viscous flow at the high temperature despite of its advantageous high purity and low contamination level for the wafer. As a result, the precision of the heat treatment and further the yield and the throughput in the manufacturing process of the IC devices may be increased.

3) The top portion and the body portion reinforcement ribs attached to the outer surface of the process tube serve as cooling fins so .that the time period for lowering the temperature in the processing chamber of the process tube can be shortened, thereby reducing the tact time of the overall process of heat treatment.

4) By the top portion and the body portion reinforcement ribs attached to the outer surface of the process tube, the robustness of the process tube against the thermal stress due to the difference in temperature between the inner and the outer surfaces of the process tube can be increased. Accordingly, the inner space of the heater (the space between the thermal insulating member and the thermal diffuser tube) can be forcedly evacuated by a cooling unit to be rapidly cooled. Therefore, the time period for lowering the temperature in the processing chamber of the process tube can be shortened, thereby further reducing the tact time of the entire process of heat treatment.

5) Since the thermal deformation of the process tube is prevented, any interference with the boat due to a failure or deformation of the process tube can be prevented. Therefore, a secondary accident by the failure or interference can be avoided, thereby increasing the safety of the hot wall furnace and the heat treatment process thereof.

6) Since the bottom ends of the body portion reinforcement ribs are substantially flushed with the bottom end of the heater, the body portion reinforcement rib does not restrict the thermal expansion of the process tube even if there occurs a difference in temperature between the upper portion of the process tube which has been heated by the heater and the lower portion of the process tube which has not been heated by the heater. Accordingly, the generation of internal stress of the process tube can be prevented so that the failure of the process tube due to the body portion reinforcement ribs attached thereto can be prevented.

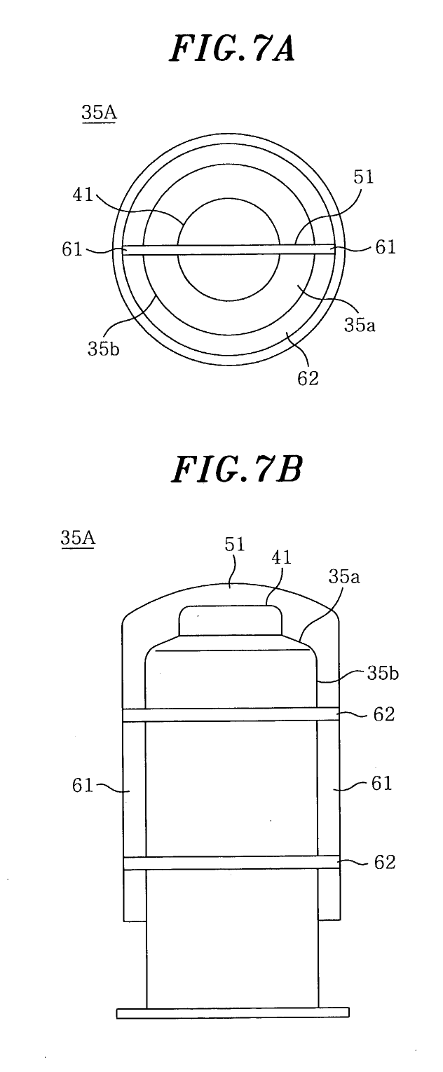

Further, the reinforcement ribs of the process tube are not limited to the configurations described in the first preferred embodiment, but may have, e.g., the configurations as shown in FIGS. 7A to 13B.

A process tube 35A in accordance with a second preferred embodiment of the present invention shown in FIGS. 7A and 7B is different from the first preferred embodiment in that the number of the body portion reinforcement ribs 61 is reduced to two and that two vertically spaced apart circular ring-shaped body portion reinforcement ribs (hereinafter, referred to as “reinforcement flanges”) 62 are horizontally disposed around the process tube 35A and connected to the two body portion reinforcement ribs 61. The two reinforcement flanges 62 serve to prevent both the swelling of the body portion 35b of the process tube 35 and the tumbling down of the body portion reinforcement ribs 61 extended vertically.

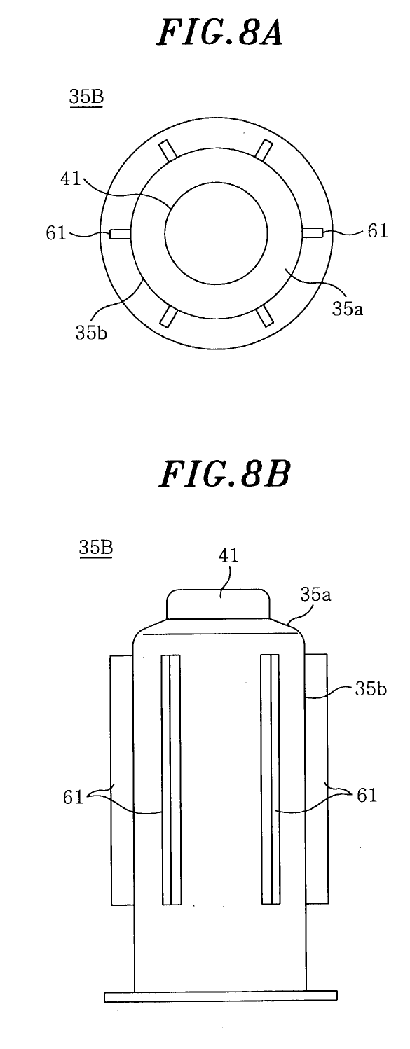

A process tube 35B in accordance with a third preferred embodiment of the present invention shown in FIGS. 8A and 8B is different from the first preferred embodiment in that the number of body portion reinforcement ribs 61 is increased to six, and that the top portion reinforcement ribs 51 are eliminated.

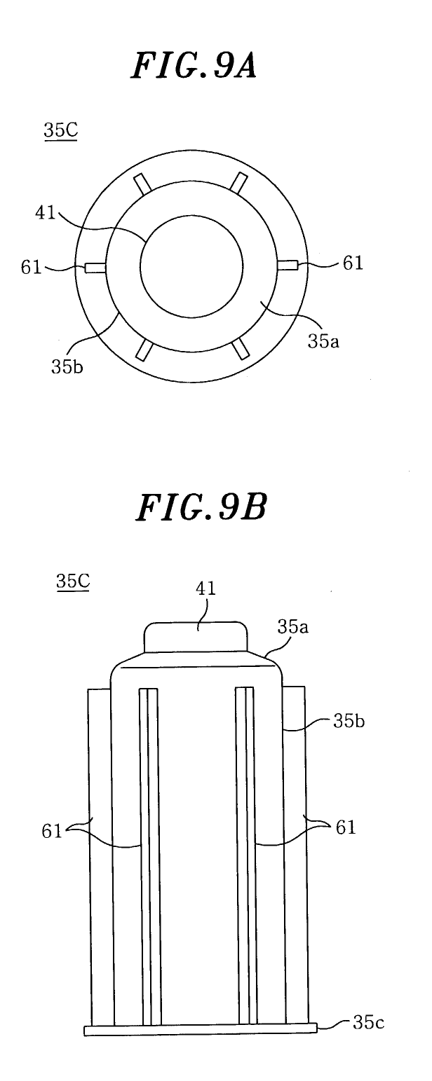

A process tube 35C in accordance with a fourth preferred embodiment of the present invention shown in FIGS. 9A and 9B is different from the first preferred embodiment in that the number of body portion reinforcement ribs 61 is increased to six and the ends of the body portion reinforcement ribs 61 are connected to a flange 35c fixed to the bottom end of the process tube and protruding laterally therefrom, and that the top portion reinforcement ribs 51 are omitted. The body portion reinforcement ribs 61 are prevented from falling down by the flange 35c of the process tube connected to the bottom end thereof.

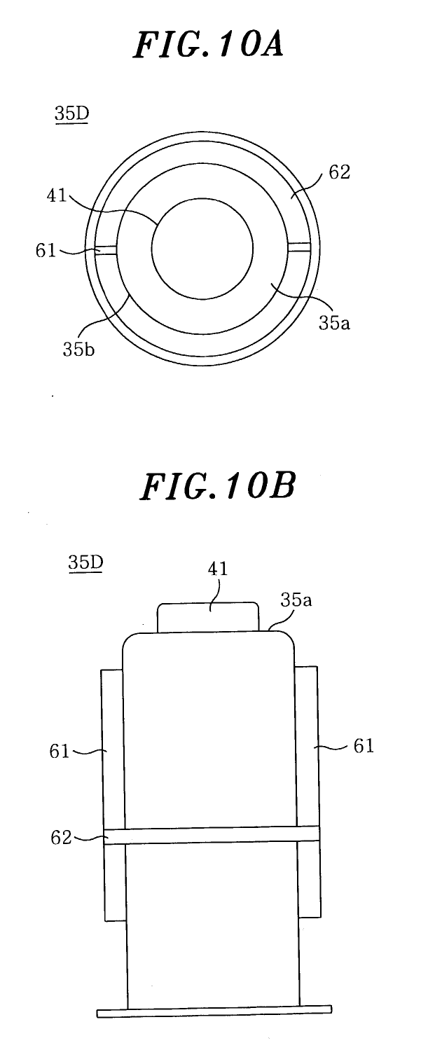

A process tube 35D in accordance with a fifth preferred embodiment of the present invention shown in FIGS. 10A and 10B is different from the first preferred embodiment in that the number of the body portion reinforcement ribs 61 is reduced to two and a reinforcement flange 62 is horizontally disposed around the process tube 35D in the vicinity of the vertically middle point thereof to be connected to the body portion reinforcement ribs 61, and that the top portion 35a has a flat shape and the top portion reinforcement ribs 51 are eliminated.

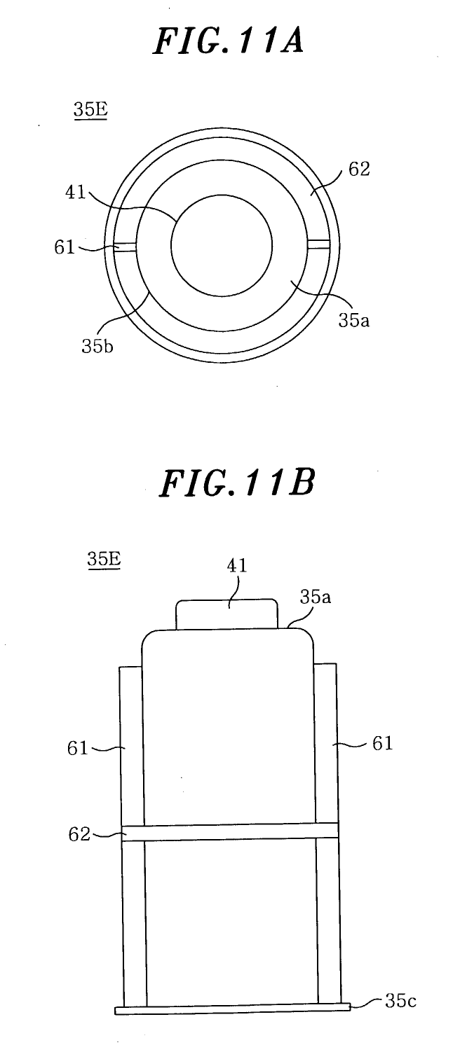

A process tube 35E in accordance with a sixth preferred embodiment of the present invention shown in FIGS. 11A and 11B is different from the first preferred embodiment in that the number of body portion reinforcement ribs 61 is reduced to two and the bottom ends of the body portion reinforcement ribs 61 are horizontally connected to the flange 35c of the process tube 35E. Further, a reinforcement flange 62 is horizontally disposed around the process tube 35E to be connected to the approximately middle portions of the body portion reinforcement ribs 61; the top portion 35a has a flat shape; and the top portion reinforcement ribs 51 are omitted.

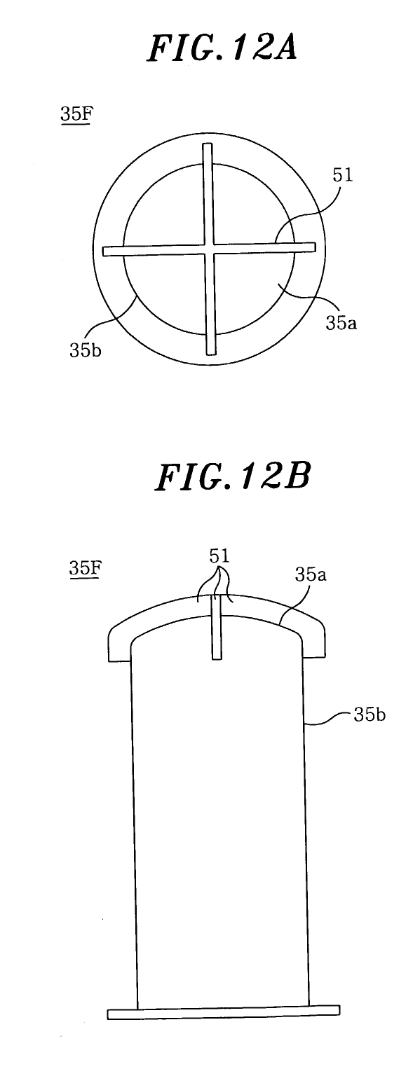

A process tube 35F in accordance with a seventh preferred embodiment of the present invention shown in FIGS. 12A and 12B is different from the first preferred embodiment in that the body portion reinforcement ribs 61 and the buffer chamber 41 are omitted.

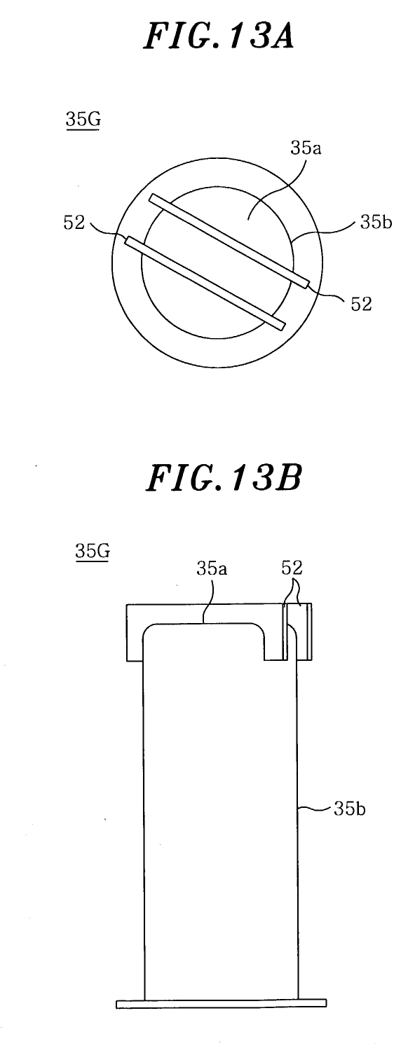

A process tube 35G in accordance with a eighth preferred embodiment of the present invention shown in FIGS. 13A and 13B is different from the first preferred embodiment in that the body portion reinforcement ribs 61 and the buffer chamber 41 are omitted; the top portion 35a has a flat shape; and two top portion reinforcement ribs 52 having an approximately rectangular shape are disposed parallel to each other.

While the invention has been shown and described with respect to the preferred embodiments, it will be understood by those skilled in the art that various changes and modifications may be made without departing from the spirit and scope of the invention as defined in the following claims.

For example, as the annealing gas, hydrogen gas may be used instead of argon gas.

Further, the present invention may be used in a process for manufacturing an SOI (silicon on insulator) wafer instead of the DZ wafer.

The present invention may also be applied to a vertical hot wall type low pressure CVD apparatus.

What is claimed is:

1. An apparatus for fabricating a semiconductor device comprising:
a reaction tube provided with at least one reinforcement member which is attached to a body portion of the reaction tube, the reinforcement member being extended in a longitudinal direction of the process tube; and
a heater surrounding the reaction tube, wherein a substrate loaded in the reaction tube is heat-treated by the heater.

2. The apparatus recited in claim 1, wherein the body portion of the reaction tube has an open end and a closed end opposite thereto, and said at least one reinforcement member is extended from the open end toward the closed end in the longitudinal direction.

3. The apparatus recited in claim 2, wherein the closed end is located substantially vertically above the open end.

4. The apparatus recited in claim 2 or 3, wherein a flange is provided to the open end of the reaction tube, and said at least one reinforcement member is extended from the flange toward the closed end.

5. The apparatus recited in claim 2 or 3, wherein the closed end of the reaction tube is formed of a closed wall and a reinforcement member is provided on the closed wall.

6. The apparatus recited in claim 5, wherein the reinforcement provided on the body portion is continuously linked to the reinforcement member provided on the closed wall.

7. The apparatus recited in any one of claims 1 to 3, wherein the number of said at least one reinforcement member is two or more and said two or more reinforcement members are circumferentially arranged at regular intervals around the body portion of the reaction tube.

8. The apparatus recited in any one of claims 1 to 3, wherein at least one ring-shaped reinforcement member is horizontally provided around the body portion of the reaction tube.

9. A method for fabricating a semiconductor device using a semiconductor device fabricating apparatus including a reaction tube having a body portion provided with two opposite ends with one end opened and the other end closed, at least one reinforcement member provided on the body portion of the reaction tube, the reinforcement member being extended from the open end toward the closed end therebetween, and a heater surrounding the reaction tube, the method comprising the steps of:
loading a substrate holding member on which a plurality of wafers are placed into the reaction tube;
heating the plurality of wafers by the heater; and
unloading, after the heating step, the substrate holding member from the reaction tube.
